(19) United States
(12) Patent Application Publication
(10) Pub. No.: US 2008/0190119 A1
(43) Pub. Date: Aug. 14, 2008

(54) PACKAGE FOR HOUSING A SEMICONDUCTOR CHIP AND METHOD FOR OPERATING A SEMICONDUCTOR CHIP AT LESS-THAN-AMBIENT TEMPERATURES

(76) Inventor: MICHAEL C. SMAYLING, Fremont, CA (US)

Correspondence Address: APPLIED MATERIALS, INC.;Patent Counsel, Legal Affairs Department, P.O. Box 450-A, Santa Clara, CA, 95035, US

(21) Appl. No.: 11/672,942

(22) Filed: Feb. 8, 2007

(51) Int. Cl. F25D 3/00; H01L 23/34

(52) U.S. Cl. 62/56; 257/707; 257/E23.08

(57) ABSTRACT

A package for housing a semiconductor chip is described. In one embodiment, the package comprises an insulation body encasing the semiconductor chip, wherein the insulation body is in direct contact with the front surface of the semiconductor chip. A refrigeration device is connected with the back surface of the semiconductor chip and is for removing substantially more heat from said semiconductor chip than the heat removed from the semiconductor chip by the insulation body. In another embodiment, a method for operating a semiconductor chip comprises cooling the semiconductor chip to a first less-than-ambient temperature by activating a refrigeration device of a package that houses the semiconductor chip. Subsequently, power is provided to the semiconductor chip, heating the semiconductor chip to a second less-than-ambient temperature.

### BACKGROUND OF THE INVENTION

1) Field of the Invention

The invention is in the field of Semiconductor Packages.

2) Description of Related Art

For the past several decades, the scaling of features in integrated circuits has been the driving force behind an ever-growing semiconductor industry. Scaling to smaller and smaller features enables increased densities of functional units on the limited real estate of semiconductor chips. For example, shrinking transistor size allows for the incorporation of an increased number of logic and memory devices onto a microprocessor, lending to the fabrication of products with increased complexity.

Scaling has not been without consequence, however. As the dimensions of the fundamental building blocks of microelectronic circuitry are reduced and as the sheer number of fundamental building blocks fabricated in a given region is increased, both power and leakage concerns have risen dramatically. More operating transistors per unit area require more input power per unit area, generating more heat per unit area. Leakage occurs when a portion of the power input to a semiconductor chip is consumed during the OFF state of certain semiconductor devices, e.g. transistors. This energy that is not consumed during the functioning of semiconductor devices in the ON state is converted to thermal energy and exacerbates the heating of a semiconductor chip. Heating can degrade the performance of semiconductor devices within an integrated circuit and, hence, cripple the capabilities of a semiconductor chip.

Semiconductor packaging has evolved to aid with mitigating the heating of semiconductor chips. For example, FIG. 1 illustrates a cross-sectional view representing a semiconductor package, in accordance with the prior art. A typical semiconductor package 100 comprises a semiconductor chip 102 housed in a highly thermal conducting material 104. The top of semiconductor chip 102, i.e. the surface which comprises the microelectronic circuitry, is accessed by connectors 106. The highly thermal conducting material 104 typically has a thermal conductivity in the range of 20-30 Watts/m·K and enables a heat gradient to form between the surface of semiconductor chip 102 and the outside environment during the operating of semiconductor chip 102. Thus, highly thermal conducting material 104 provides a pathway through which heat can escape from semiconductor chip 102. Furthermore, a typical semiconductor package may comprise a refrigeration device 110 attached to a heat spreader 108 and a radiator 112. The refrigeration device 110 may provide another pathway through which heat can escape from semiconductor chip 102.

FIG. 2 illustrates a thermodynamic representation of a typical semiconductor package 200 comprising an operating semiconductor chip 202 packaged in a highly thermal conducting material, in accordance with the prior art. Operating semiconductor chip 202 heats to a temperature (T_{junction}) that is above the outside temperature (T_{ambient}). The incorporation of a highly thermal conducting material to encase operating semiconductor chip 202 results in a package resistance (R_{package}) that is low. Thus, a significant portion of the heat removed from operating semiconductor chip 202 is removed through the packaging material itself. The packaged semiconductor chip 202 has a thermal mass (C_{chip+package}) and, also, a natural thermal gradient forms between T_{junction} and T_{ambient}. Although heat is allowed to escape, operating semiconductor chip 202 is located at the high end of the temperature gradient and may thus experience a relatively high localized temperature, i.e. T_{junction}>T_{ambient}. A relatively high input power Pᵢₙ may be required to operate packaged semiconductor chip 202 but may not be acceptable, especially in cases where low power applications are desired.

Thus, a package for housing a semiconductor chip is described herein, along with a method for operating a semiconductor chip at a temperature below ambient.

### BRIEF DESCRIPTION OF THE DRAWINGS

FIG. 1 illustrates a cross-sectional view representing a semiconductor package, in accordance with the prior art.

FIG. 2 illustrates a thermodynamic representation of a semiconductor package comprising an operating semiconductor chip, in accordance with the prior art.

FIG. 3 illustrates a cross-sectional view representing a semiconductor package having an insulation body, in accordance with an embodiment of the present invention.

FIG. 4 illustrates a cross-sectional view representing a semiconductor package having an insulation body with two components, in accordance with an embodiment of the present invention.

FIG. 5 is a Flowchart representing a series of steps for operating a semiconductor chip, in accordance with an embodiment of the present invention.

FIG. 6 illustrates a thermodynamic representation of a semiconductor package comprising an operating semiconductor chip, in accordance with an embodiment of the present invention.

FIG. 7 is a Flowchart representing a series of steps for operating a semiconductor chip at a less-than-ambient temperature, in accordance with an embodiment of the present invention.

FIG. 8 illustrates a plot of Applied Voltage (Vds) versus Output Current (Id) of a metal-oxide-semiconductor field-effect-transistor (MOS-FET) device on a semiconductor chip operating at temperatures in the range of −100° C.-100° C., in accordance with an embodiment of the present invention.

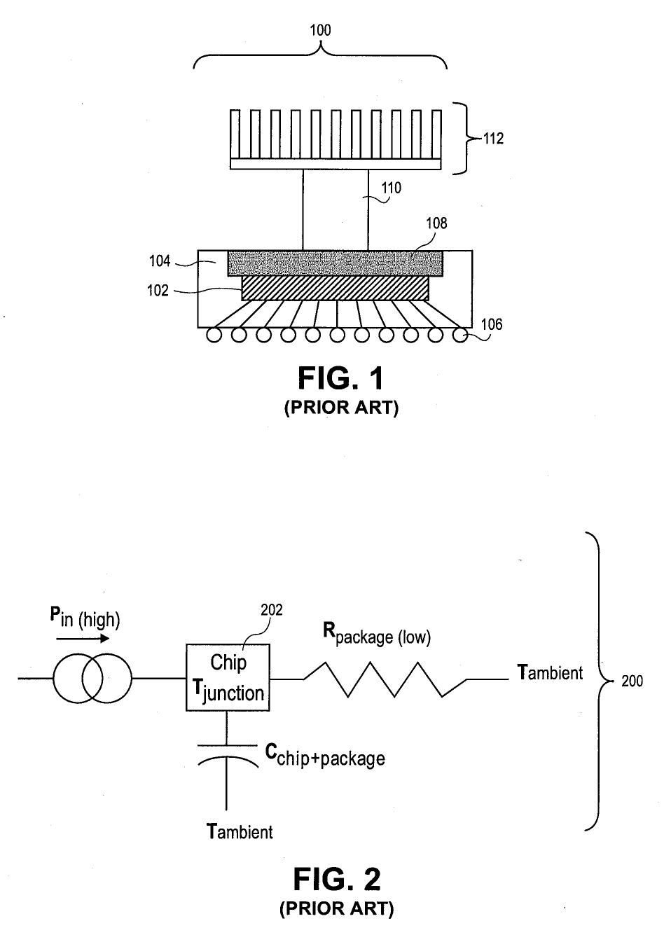

### DETAILED DESCRIPTION

A package for housing semiconductor chips is described. In the following description, numerous specific details are set forth, such as operating conditions and material regimes, in order to provide a thorough understanding of the present invention. It will be apparent to one skilled in the art that the present invention may be practiced without these specific details. In other instances, well-known features, such as transistor architectures and integrated circuit design layouts, are not described in detail in order to not unnecessarily obscure the present invention. Furthermore, it is to be understood that the various embodiments shown in the figures are illustrative representations and are not necessarily drawn to scale.

Disclosed herein are a package for housing a semiconductor chip and a corresponding method for operating a semiconductor chip at a temperature below ambient. The package may comprise an insulation body encasing a semiconductor chip and in direct contact with the front surface of the semiconductor chip. In one embodiment, a refrigeration device is connected with the back surface of the semiconductor chip and is for removing substantially more heat from the semiconductor chip than the heat removed from the semiconductor chip by the insulation body. A method for operating a semiconductor chip may comprise a first step of cooling the semiconductor chip to a less-than-ambient temperature by activating a refrigeration device of a package that houses the semiconductor chip. In an embodiment, an insulation body blocks heat outside the package from accessing the semiconductor chip.

The incorporation of an insulation body, i.e. one comprising a material having low thermal conductivity, to encase an operating semiconductor chip may enable a significant reduction in the amount of heat flow through the packaging material. Thus, in accordance with an embodiment of the present invention, an affiliated refrigeration device is the primary pathway for heat removal. Under less-than-ambient operating conditions, although some of the pathways for heat removal are eliminated, the localized temperature of an operating semiconductor chip is in fact reduced by mitigating the formation of thermal gradients that surround the operating chip—thermal gradients that could otherwise allow heating of the semiconductor chip by the environment outside of the package. In one embodiment, the input power needed to operate a semiconductor chip is lessened as a consequence of removing substantially more heat from the semiconductor chip by way of a refrigeration device as compared with the heat removed through the packaging material. Furthermore, in accordance with another embodiment of the present invention, a packaged semiconductor chip is cooled prior to the inputting of power to operate the semiconductor chip, enabling the operation of a semiconductor chip at a less-than-ambient temperature. In a specific embodiment, an insulation body blocks heat outside of the package from accessing the semiconductor chip while it operates at a less-than-ambient temperature.

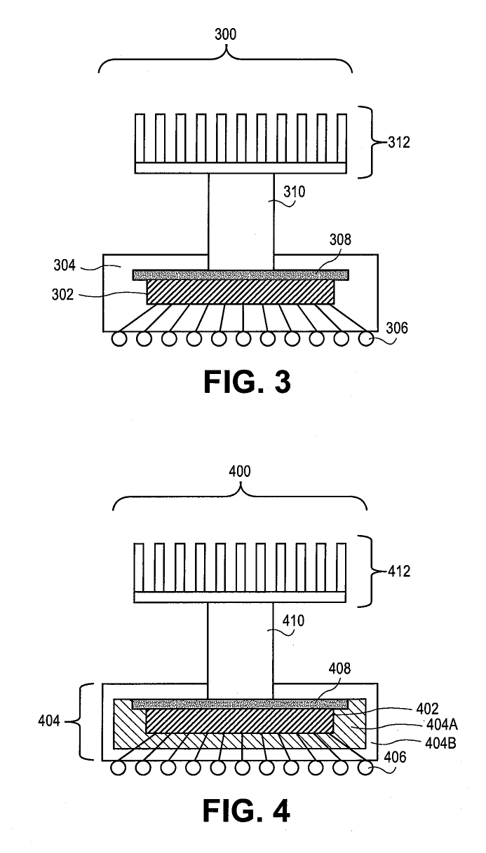

A semiconductor package may incorporate an insulation body adjacent to a semiconductor chip. FIG. 3 illustrates a cross-sectional view representing a semiconductor package having an insulation body, in accordance with an embodiment of the present invention.

Referring to FIG. 3, semiconductor package 300 comprises a semiconductor chip 302 encased in insulation body 304. The front surface of semiconductor chip 302, i.e. the surface comprising semiconductor device layers, is in direct contact with insulation body 304. Furthermore, the front surface of semiconductor chip 302 is connected externally via connectors 306, which run through insulation body 304. The back surface of semiconductor chip 302 is connected with refrigeration device 310. Refrigeration device 310 may further comprise a heat interface layer 308 and a radiator 312, as depicted in FIG. 3.

Semiconductor chip 302 may be comprised of any semiconductor die, or group of dice, for use in the semiconductor industry. In one embodiment, semiconductor chip 302 is a microprocessor formed from a silicon substrate. In another embodiment, semiconductor chip 302 is a diode formed on a III-V material substrate. Semiconductor chip 302 may represent a platform of several units housed together. For example, in an embodiment, semiconductor chip 302 comprises a microprocessor die coupled with an RF die for wireless connectivity. Semiconductor chip 302 may have a surface comprising a micro-electronic integrated circuit. In one embodiment, semiconductor chip 302 has a surface comprising an array of CMOS transistors connected with connectors 306 through a series of metal interconnects. Connectors 306 may be any entity suitable to externally connect semiconductor chip 302 with an outside circuitry. In one embodiment, connectors 306 are comprised of a series of wires connected with external solder balls, as depicted in FIG. 3. In another embodiment, connectors 306 are comprised of optical waveguides for transmitting an optical signal to an outside circuitry. In an embodiment, connectors 306 are comprised of tape connectors with electrical traces formed therein.

Insulation body 304 may be positioned relative to semiconductor chip 302 in any manner suitable to substantially inhibit formation of a pathway for heat displacement via the front surface of semiconductor chip 302, i.e. the surface comprising semiconductor device layers. In one embodiment, insulation body 304 is directly adjacent to the front surface of said semiconductor chip 302. In a specific embodiment, insulation body 304 wraps around semiconductor chip 302 and above the surface of semiconductor chip 302 connected with refrigeration device 310, as depicted in FIG. 3.

Insulation body 304 may be comprised of any material suitable to substantially inhibit formation of a pathway for heat displacement. In accordance with an embodiment of the present invention, insulation body 304 is comprised of a material having low thermal conductivity. In one embodiment, insulation body 304 is comprised of a material having a thermal conductivity below 10 Watts/m·K. In a specific embodiment, insulation body 304 is comprised of a material having a thermal conductivity in the range of 1-5 Watts/m·K and is selected from the group consisting of a glass, a ceramic, an epoxy resin, a polyacrylic plastic, a polycarbonate plastic, a polyethylene plastic, a polyolefin plastic, a polypropylene plastic, a polystyrene plastic, a polyurethane plastic, a polyvinyl chloride plastic and a vinylic plastic. Insulation body 304 may have a thickness suitable to substantially protect semiconductor chip 302 from heating by the external environment. In an embodiment, insulation body 304 has a thickness of at least 0.5 millimeters. In one embodiment, insulation body 304 has a thickness in the range of 1 millimeter-1 centimeter.

Refrigeration device 310 may be comprised of any mechanism or material capable of displacing heat from semiconductor chip 302 to the outside of semiconductor package 300. In accordance with an embodiment of the present invention, refrigeration device 310 is for removing substantially more heat from semiconductor chip 302 than the heat displaced by insulation body 304. In a specific embodiment, refrigeration device 310 is for removing greater than 10 times more heat from semiconductor chip 302 than the heat removed from semiconductor chip 302 by insulation body 304. In an embodiment, refrigeration device 310 is comprised of a cooling mechanism selected from the group consisting of a high thermal conductivity material, a circulating cooling liquid and a fan. In a particular embodiment, refrigeration device 310 is comprised of a block of copper metal connected with a heat sink. In an alternative embodiment, refrigeration device 310 is comprised of a circulating glycol liquid cooling system. In another embodiment, although not shown, refrigeration device 310 is further comprised of a series of heat pipes.

Radiator 312 may be comprised of any device or material suitable to enhance heat displacement from semiconductor package 300 by refrigeration device 310. In one embodiment, radiator 312 is comprised of a material with a higher thermal conductivity than the thermal conductivity of refrigeration device 310, forming a heat sink. Radiator 312 may be formed to maximize the surface area of the structure of radiator 312 in order to enable a highly efficient heat displacement scheme. In one embodiment, radiator 312 is comprised of micro-fins, as depicted in FIG. 3.

Semiconductor package 300 may further comprise a heat interface layer 308 for providing a buffer between semiconductor chip 302 and refrigeration device 310, as depicted in FIG. 3. In an embodiment, heat interface layer provides a heat sink for quick thermal transport away from semiconductor chip 302. In one embodiment, heat interface layer 308 is comprised of micro-channels for rapid thermal transport. Alternatively, semiconductor package 300 may not comprise a heat interface layer between semiconductor chip 302 and refrigeration device 310. In accordance with an alternative embodiment of the present invention, semiconductor chip 302 is comprised of a bulk silicon substrate, the back side of which provides a sufficient thermal buffer to enable direct contact between semiconductor chip 302 and refrigeration device 310.

A semiconductor package may have an insulation body comprising two or more components. FIG. 4 illustrates a cross-sectional view representing a semiconductor package having an insulation body with two components, in accordance with an embodiment of the present invention.

Referring to FIG. 4, semiconductor package 400 comprises a semiconductor chip 402 encased in two-component insulation body 404. The front surface of semiconductor chip 402, i.e. the surface comprising semiconductor device layers, is in direct contact with two-component insulation body 404. Furthermore, the front surface of semiconductor chip 402 is connected externally via connectors 406, which run through two-component insulation body 404. The back surface of semiconductor chip 402 is connected with refrigeration device 410. Refrigeration device 410 may further comprise a heat interface layer 408 and a radiator 412, as depicted in FIG. 4. Semiconductor chip 402, connectors 406, heat interface layer 408, refrigeration device 410 and radiator 412 may be comprised of any material and may embody any configuration discussed in association with semiconductor chip 302, connectors 306, heat interface layer 308, refrigeration device 310 and radiator 312, respectively, from FIG. 3.

Two-component insulation body 404 may be comprised of any pair of materials suitable for providing both insulation for semiconductor chip 402 and durability to semiconductor package 400. In accordance with an embodiment of the present invention, two-component insulation body 404 is comprised of first material 404A and second material 404B, wherein first material 404A is directly adjacent to the front surface of semiconductor chip 402, as depicted in FIG. 4. Insulation body 404 may be positioned relative to semiconductor chip 402 in any manner suitable to substantially inhibit formation of a pathway for heat displacement via the front surface of semiconductor chip 402, i.e. the surface comprising semiconductor device layers. In one embodiment, insulation body 404 is directly adjacent to the front surface of said semiconductor chip 402. In a specific embodiment, insulation body 404 wraps around semiconductor chip 402 and above the surface of semiconductor chip 402 connected with refrigeration device 410, as depicted in FIG. 4.

First material 404A of insulation body 404 may be comprised of any material suitable to substantially inhibit formation of a pathway for heat displacement. In accordance with an embodiment of the present invention, first material 404A is comprised of a material having low thermal conductivity. In one embodiment, first material 404A is comprised of a material having a thermal conductivity below 10 Watts/m·K. In a specific embodiment, insulation body 304 is comprised of a material having a thermal conductivity in the range of 1-5 Watts/m·K and is selected from the group consisting of a glass, a ceramic, an epoxy resin, a polyacrylic plastic, a polycarbonate plastic, a polyethylene plastic, a polyolefin plastic, a polypropylene plastic, a polystyrene plastic, a polyurethane plastic, a polyvinyl chloride plastic and a vinylic plastic. In another embodiment, first material 404A has a thermal conductivity of less than 1 Watt/m·K and is comprised a silica aerogel having a porosity in the range of 50-99%. In an alternative embodiment, first material 404A is comprised of a non-silica aerogel selected from the group consisting of carbon, alumina, titania, germania, zirconia, niobia, tin oxide and hafnia. First material 404A may have a thickness suitable to substantially block all heat dissipation pathways within two-component insulation body 404. In an embodiment, first material 404A has a thickness of at least 0.3 millimeters. In one embodiment, first material 404A has a thickness in the range of 1-5 millimeters.

Second material 404B of insulation body 404 may be comprised of any material suitable to provide mechanical integrity to semiconductor package 400. In accordance with an embodiment of the present invention, second material 404B is comprised of an insulating material with a higher thermal conductivity that first material 404A. In another embodiment, second material 404B is comprised of a metal and is malleable. In one embodiment, second material 404B consists substantially of aluminum or copper. In a specific embodiment, second material 404B is reinforced by the incorporation of an array of carbon nanotubes. Second material 404B may have a thickness suitable to substantially protect semiconductor chip 402 from external impact. In an embodiment, second material 404B has a thickness of at least 1 millimeter. In one embodiment, second material 404B has a thickness in the range of 3-5 millimeters. In a specific embodiment, second material 404B has a thickness of at least twice the thickness of first material 404A.

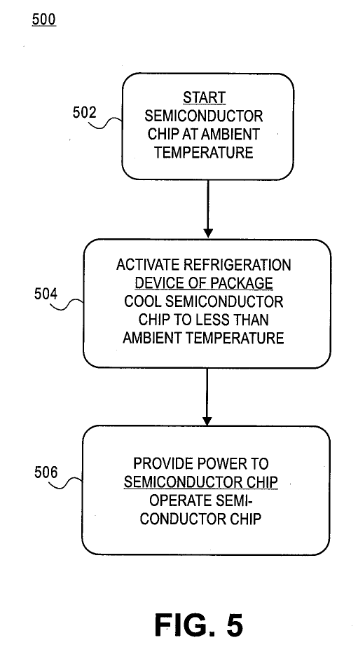

A semiconductor chip housed in a semiconductor package comprising an insulating body may be operated at a less-than-ambient temperature. FIG. 5 is a Flowchart representing a series of steps for operating a semiconductor chip, in accordance with an embodiment of the present invention.

Referring to step 502 of Flowchart 500, a non-operating semiconductor chip is at ambient temperature. In an embodiment, a semiconductor package substantially similar to semiconductor packages 300 and 400 described in association with FIGS. 3 and 4, respectively, is used to house the semiconductor chip. The ambient temperature may be any temperature suitable to operate a computing device that employs the semiconductor chip. In an embodiment, the ambient temperature is above 10 degrees Celsius. In one embodiment, the ambient temperature is in the range of 15-30 degrees Celsius.

Referring to step 504 of Flowchart 500, a refrigeration device of the package that houses a semiconductor chip for operation may be activated prior to the operation of the semiconductor chip. Thus, in accordance with an embodiment of the present invention, a semiconductor chip is cooled to a less-than-ambient temperature prior to its operation. In one embodiment, the semiconductor chip is cooled to a temperature in the range of −100-−50 degrees Celsius. A semiconductor package comprised of an insulation body that houses the semiconductor chip may aid with cooling the semiconductor chip. Thus, in accordance with another embodiment of the present invention, an insulation body blocks heat outside of the semiconductor package from accessing the semiconductor chip once it is cooled to a less-than-ambient temperature. The timing of step 504 may be of a duration sufficient to cool the chip to a specifically desired less-than-ambient temperature without substantially delaying the subsequent operation of the semiconductor chip. In one embodiment, a semiconductor chip housed in a semiconductor package comprised of an insulation body is cooled to a desired less-than-ambient temperature in less than one minute.

Referring to step 506 of Flowchart 500, power is provided to operate the semiconductor chip that was previously cooled to a less-than-ambient temperature in step 504. The power provided may be sufficient to operate a state-of-the-art integrated circuit. In accordance with an embodiment of the present invention, the providing of power to operate the semiconductor chip heats the semiconductor chip to a second temperature, wherein the second temperature is above the less-than-ambient temperature achieved in step 504. In one embodiment, the second temperature is a second less-than-ambient temperature. In a specific embodiment, the second temperature is a second less-than-ambient temperature and is within 10 degrees Celsius of the less-than-ambient temperature achieved in step 504. In an embodiment, at step 506, substantially more heat is removed from the operating semiconductor chip via a refrigeration device of the semiconductor package than is removed via an insulation body of the semiconductor package. The insulation body encases the semiconductor chip and is in direct contact with the front surface of the semiconductor chip.

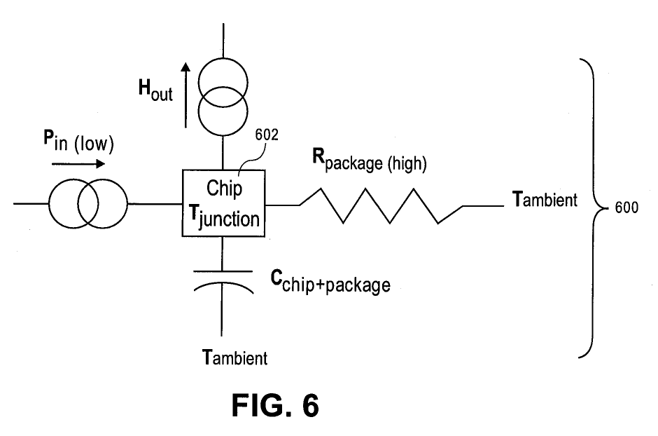

The operation of a semiconductor chip at a less-than-ambient temperature, wherein the semiconductor chip is housed in a semiconductor package having an insulation body, may impact the thermodynamic relationships between the semiconductor chip, the semiconductor package and the external environment. FIG. 6 illustrates a thermodynamic representation of a semiconductor package comprising an operating semiconductor chip, in accordance with an embodiment of the present invention.

Referring to FIG. 6, a semiconductor package 600 comprises an operating semiconductor chip 602 packaged in a low thermal conducting material, i.e. an insulating body. The incorporation of an insulating body to encase operating semiconductor chip 602 may result in a package resistance (R_{package}) that is high. Thus, a significant portion of the heat removed (Hₒᵤₜ) from operating semiconductor chip 602 can be removed through a refrigeration device rather than through the packaging material itself. Furthermore, operating semiconductor chip 602 may be operated at a less-than-ambient temperature, as described in association with Flowchart 500 from FIG. 5. Thus, in accordance with an embodiment of the present invention, T_{junction}<T_{ambient}. In one embodiment, an insulation body blocks heat outside of semiconductor package 600 from accessing semiconductor chip 602 and thus hinders the formation of natural thermal gradients between T_{junction} and T_{ambient} via the packaging material. A low input power (Pᵢₙ) may be all that is required to operate semiconductor chip 602 since the operating efficiency may increase with decreasing T_{junction}, e.g. by way of a reduction in leakage current for semiconductor devices on semiconductor chip 602. Thus, in accordance with an embodiment of the present invention, semiconductor chip 602 is cooled to a less-than-ambient temperature to reduce the input power required to operate semiconductor chip 602 in semiconductor package 600. The amount of heat requiring removal from semiconductor chip 602 in semiconductor package 600 may thus be mitigated, enhancing the refrigeration ability of a refrigeration device in semiconductor package 600.

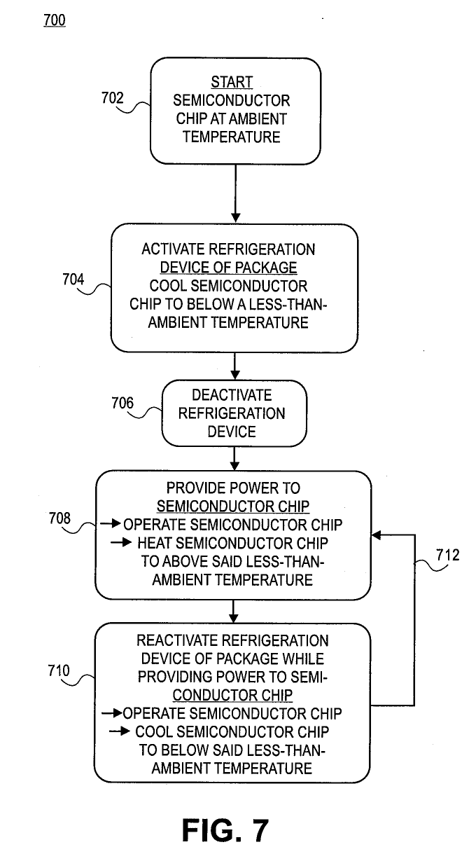

A semiconductor chip housed in a semiconductor package comprising an insulating body may be operated at a less-than-ambient temperature while exercising a refrigeration device activation/deactivation cycle. FIG. 7 is a Flowchart representing a series of steps for operating a semiconductor chip at a less-than-ambient temperature, in accordance with an embodiment of the present invention.

Referring to step 702 of Flowchart 700, a non-operating semiconductor chip is at ambient temperature. In an embodiment, a semiconductor package substantially similar to semiconductor packages 300 and 400 described in association with FIGS. 3 and 4, respectively, is used to house the semiconductor chip. The ambient temperature may be any temperature described in association with the ambient temperature of step 502 from FIG. 5. Referring to step 704 of Flowchart 700, a refrigeration device of the package that houses a semiconductor chip for operation may be activated prior to the operation of the semiconductor chip. Thus, in accordance with an embodiment of the present invention, a semiconductor chip is cooled to below a targeted less-than-ambient temperature prior to its operation. In one embodiment, the targeted less-than-ambient temperature is in the range of −100-−50 degrees. The functions of the insulating body with respect to cooling the semiconductor device and the timing of step 704 may be the same as those described in association with step 504 of FIG. 5.

Referring to step 706 of Flowchart 700, the refrigeration device of the semiconductor package that houses the semiconductor chip cooled to below the targeted less-than-ambient temperature in step 704 may be deactivated. In one embodiment, the refrigeration device is deactivated when a targeted temperature in the range of −100-−50 degrees Celsius is achieved. In an alternative embodiment, the deactivation of the refrigeration device, i.e. step 706, is eliminated prior to operating the semiconductor device.

Referring to step 708 of Flowchart 700, power is provided to operate the semiconductor chip that was previously cooled to below the targeted less-than-ambient temperature in step 704. The power provided may be sufficient to operate a state-of-the-art integrated circuit. In accordance with an embodiment of the present invention, the providing of power to operate the semiconductor chip eventually heats the semiconductor chip to above the targeted less-than-ambient temperature achieved in step 704. In an embodiment, at step 708, substantially more heat is removed from the operating semiconductor chip via the refrigeration device of the semiconductor package than is removed via the insulation body of the semiconductor chip. In one embodiment, the insulation body encases the semiconductor chip and is in direct contact with the front surface of the semiconductor chip and blocks outside heat from accessing the semiconductor chip.

Referring to step 710 of Flowchart 700, when the temperature of the operating semiconductor chip rises above the targeted less-than-ambient temperature, the refrigeration device of the semiconductor package is reactivated. In accordance with an embodiment of the present invention, the refrigeration device is maintained in an ON state until the temperature of the operating semiconductor chip falls once again below the targeted less-than-ambient temperature. In one embodiment, the refrigeration device is deactivated when the targeted less,-than-ambient temperature is achieved. Referring to step 712 of Flowchart, the activating and reactivating of the refrigeration device may be repeated as necessary during the operating of the semiconductor chip at a less-than-ambient temperature. Thus, in accordance with an embodiment of the present invention, operating a semiconductor chip at a less than ambient temperature comprises exercising a cycle combining the steps of (1) activating a refrigeration device to cool the semiconductor chip to below a targeted less-than-ambient temperature whenever the temperature of the semiconductor chip rises above the targeted less-than-ambient temperature and (2) deactivating the refrigeration device whenever the temperature of said semiconductor chip falls below the targeted less-than-ambient temperature. In one embodiment, the activation/deactivation cycle of the refrigeration device is determined by an output signal from a diode that measures the temperature of the operating semiconductor device.

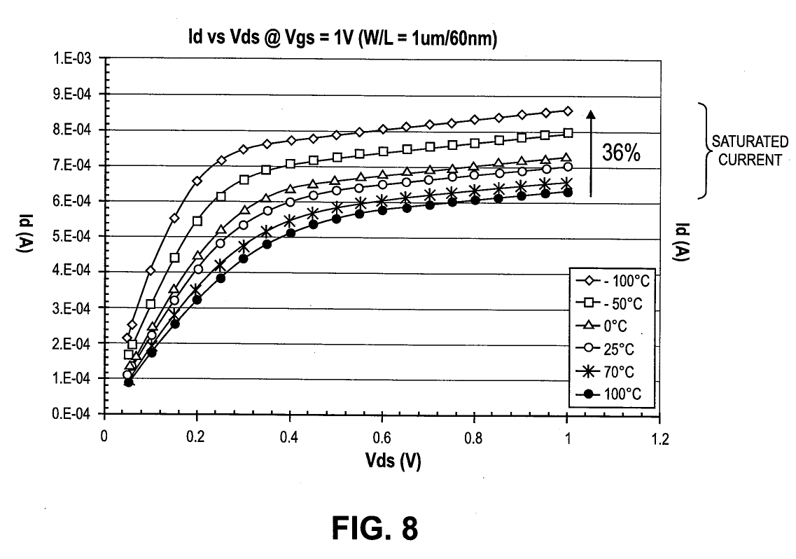

The operating of a semiconductor chip at a less-than-ambient temperature may enable performance improvement of semiconductor devices that reside on the semiconductor chip, as compared with semiconductor devices that are operated at or above an ambient temperature. FIG. 8 illustrates a plot of Applied Voltage (Vds) versus Output Current (Id) of a metal-oxide-semiconductor field-effect-transistor (MOS-FET) device on a semiconductor chip operating at temperatures in the range of −100° C.-100° C., in accordance with an embodiment of the present invention.

Referring to FIG. 8, the saturated current of the Output Current (Id) of a MOS-FET increases with decreasing temperature. Thus, in accordance with an embodiment of the present invention, the performance of a semiconductor device is improved by operating a semiconductor chip at a less-than-ambient temperature. This change in Output Current (Id) with temperature may be used to signal a refrigeration device in a semiconductor package. Thus, in accordance with another embodiment of the present invention, the exercising of an activation/deactivation cycle of a refrigeration device is determined by the saturated drive current of a transistor on a semiconductor chip operating at a less-than-ambient temperature. In a specific embodiment, the exercising of an activation/deactivation cycle of a refrigeration device comprises responding to a reduction in the saturated drive current of greater than 10% of the saturated drive current of the transistor as measured at a targeted less-than ambient temperature.

Thus, a package for housing a semiconductor chip has been disclosed. In one embodiment, the package comprises an insulation body encasing the semiconductor chip, wherein the insulation body is in direct contact with the front surface of the semiconductor chip. A refrigeration device is connected with the back surface of the semiconductor chip and is for removing substantially more heat from said semiconductor chip than the heat removed from the semiconductor chip by the insulation body. In another embodiment, a method for operating a semiconductor chip comprises cooling the semiconductor chip to a first, less-than-ambient, temperature by activating a refrigeration device of a package that houses the semiconductor chip. Subsequently, power is provided to the semiconductor chip, heating the semiconductor chip to a second less-than-ambient temperature.

What is claimed is:

1. A package for housing a semiconductor chip comprising:
an insulation body encasing said semiconductor chip, wherein said insulation body is in direct contact with the front surface of said semiconductor chip, and wherein said insulation body is comprised of a material having a thermal conductivity below 10 Watts/m·K; and
a refrigeration device connected with the back surface of said semiconductor chip, wherein said refrigeration device is for removing substantially more heat from said semiconductor chip than the heat removed from said semiconductor chip by said insulation body.

2. The package of claim 1 wherein said refrigeration device is for removing greater than 10 times more heat from said semiconductor chip than the heat removed from said semiconductor chip by said insulation body.

3. The package of claim 1 wherein said material has a thermal conductivity in the range of 1-5 Watts/m·K and is selected from the group consisting of a glass, a ceramic, an epoxy resin, a polyacrylic plastic, a polycarbonate plastic, a polyethylene plastic, a polyolefin plastic, a polypropylene plastic, a polystyrene plastic, a polyurethane plastic, a polyvinyl chloride plastic and a vinylic plastic.

4. The package of claim 1 wherein said insulation body is comprised of a first material and a second material, wherein said first material is directly adjacent to the front surface of said semiconductor chip and has a thermal conductivity of less than 1 Watt/m·K, and wherein said second material is for providing a high mechanical strength to said package.

5. The package of claim 4 wherein said first material is comprised of a silica aerogel having a porosity in the range of 50-99%, wherein said second material is comprised of a metal, and wherein said second material is malleable.

6. The package of claim 4 wherein said first material is comprised of a non-silica aerogel selected from the group consisting of carbon, alumina, titania, germania, zirconia, niobia, tin oxide and hafnia.

7. The package of claim 1 wherein said refrigeration device is comprised of a cooling mechanism selected from the group consisting of a high thermal conductivity material, a circulating cooling liquid and a fan.

8. A method for operating a semiconductor chip comprising:
cooling said semiconductor chip to a first temperature by activating a refrigeration device of a package that houses said semiconductor chip, wherein said first temperature is less than an ambient temperature, and wherein said package comprises:
an insulation body encasing said semiconductor chip, wherein said insulation body is in direct contact with the front surface of said semiconductor chip; and
said refrigeration device connected with the back surface of said semiconductor chip, wherein said refrigeration device is for removing substantially more heat from said semiconductor chip than the heat removed from said semiconductor chip by said insulation body; and,
subsequent to cooling said semiconductor chip to said first temperature, providing power to said semiconductor chip to operate said semiconductor chip.

9. The method of claim 8 wherein providing power heats said semiconductor chip to a second temperature.

10. The method of claim 9 wherein cooling said semiconductor chip reduces the power required to operate said semiconductor chip relative to the power required at said ambient temperature.

11. The method claim 10 wherein said first temperature is in the range of −100-−50 degrees Celsius.

12. The method of claim 9 wherein said second temperature is less than said ambient temperature, and wherein said second temperature is within 10 degrees Celsius of said first temperature.

13. The method of claim 9 wherein said insulation body blocks heat outside of said package from accessing said semiconductor chip.

14. A method for maintaining an operating semiconductor chip at a temperature below ambient comprising:
activating a refrigeration device of a package that houses said semiconductor chip to cool said semiconductor chip to below a less-than-ambient temperature; and, subsequent to activating said refrigeration device,
deactivating said refrigeration device;
providing power to said semiconductor chip to operate said semiconductor chip, wherein providing power heats said semiconductor chip; and, during the providing of power to said semiconductor chip,
exercising a cycle comprising the steps of (1) reactivating said refrigeration device to cool said semiconductor chip to below said less-than-ambient temperature whenever the temperature of said semiconductor chip rises above said less-than-ambient temperature and (2) deactivating said refrigeration device whenever the temperature of said semiconductor chip falls below said less-than-ambient temperature.

15. The method claim 14 wherein said less-than ambient temperature is in the range of −100-−50 degrees Celsius.

16. The method of claim 14 wherein the temperature of said semiconductor chip during the exercising of said cycle is determined by the saturated drive current of a transistor on said semiconductor chip.

17. The method of claim 16 wherein reactivating said refrigeration device comprises responding to a reduction in the saturated drive current of said transistor, and wherein said reduction is a reduction in saturated drive current of greater than 10% of the saturated drive current of said transistor as measured at said less-than ambient temperature.

18. The method of claim 14 wherein said package comprises:
an insulation body encasing said semiconductor chip, wherein said insulation body is in direct contact with the front surface of said semiconductor chip; and
said refrigeration device connected with the back surface of said semiconductor chip, wherein said refrigeration device is for removing substantially more heat from said semiconductor chip than the heat removed from said semiconductor chip by said insulation body.

19. The method of claim 18 wherein said refrigeration device is for removing greater than 10 times more heat from said semiconductor chip than the heat removed from said semiconductor chip by said insulation body.

20. The method of claim 18 wherein said insulation body is comprised of a material having a thermal conductivity below 10 Watts/m·K, and wherein said material is directly adjacent to the front surface of said semiconductor chip.
